(19) United States
(12) Patent Application Publication
(10) Pub. No.: US 2014/0252521 A1
(43) Pub. Date: Sep. 11, 2014

(54) Image Sensor with Improved Dark Current Performance

(71) Applicant: TAIWAN SEMICONDUCTOR MANUFACTURING COMPANY, LTD., Hsin-Chu (TW)

(72) Inventors: Min-Feng Kao, Chiayi City (TW); Dun-Nian Yaung, Taipei City (TW); Jen-Cheng Liu, Hsin-Chu City (TW); Feng-Chi Hung, Chu-Bei City (TW); Shuang-Ji Tsai, Tainan City (TW); Jeng-Shyan Lin, Tainan City (TW); Chun-Chieh Chuang, Tainan City (TW)

(21) Appl. No.: 14/030,073

(22) Filed: Sep. 18, 2013

Related U.S. Application Data
(60) Provisional application No. 61/775,957, filed on Mar. 11, 2013.

(51) Int. Cl. H01L 31/0216

(52) U.S. Cl. CPC H01L 31/02161
USPC 257/432; 438/69

(57) ABSTRACT

Provided is a semiconductor image sensor device. The image sensor device includes a semiconductor substrate having a first side and a second side opposite the first side. The semiconductor substrate contains a radiation-sensing region configured to sense radiation projected toward the substrate from the second side. A first layer is disposed over the second side of the semiconductor substrate. The first layer has a first energy band gap. A second layer is disposed over the first layer. The second layer has a second energy band gap. A third layer is disposed over the second layer. The third layer has a third energy band gap. The second energy band gap is smaller than the first energy band gap and the third energy band gap.

### PRIORITY DATA

The present application is a utility patent application of U.S. provisional patent application No. 61/775,957, filed on Mar. 11, 2013, entitled “Image Sensor With Improved Dark Current Performance”, attorney docket 2012-1275/24061.2390, the disclosure of which is hereby incorporated by reference in its entirety.

### BACKGROUND

Semiconductor image sensors are used to sense radiation such as light. Complementary metal-oxide-semiconductor (CMOS) image sensors (CIS) and charge-coupled device (CCD) sensors are widely used in various applications such as digital still camera or mobile phone camera applications. These devices utilize an array of pixels in a substrate, including photodiodes and transistors, that can absorb radiation projected toward the substrate and convert the sensed radiation into electrical signals.

A back side illuminated (BSI) image sensor device is one type of image sensor device. These BSI image sensor devices are configured to detect light projected from the backside. However, existing methods of fabricating BSI image sensor devices may still suffer from problems such as dark current, white pixel, dark image non-uniformity, etc. These problems may be caused by external excess charge carriers, which may be produced during the fabrication of the BSI image sensor devices, such as plasma etching processes. An effective structure or method of reducing or alleviating these aforementioned problems has not been proposed.

Therefore, while existing semiconductor image sensors have been generally adequate for their intended purposes, they are not entirely satisfactory in every aspect.

### BRIEF DESCRIPTION OF THE DRAWINGS

Aspects of the present disclosure are understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart illustrating a method for fabricating an image sensor device according to various aspects of the present disclosure.

FIGS. 2-5 and 7 are diagrammatic fragmentary cross-sectional side views of an image sensor device at various stages of fabrication in accordance with various aspects of the present disclosure.

FIG. 6 is a simplified energy band diagram in accordance with various aspects of the present disclosure.

### DETAILED DESCRIPTION

It is to be understood that the following disclosure provides many different embodiments, or examples, for implementing different features of the invention. Specific examples of components and arrangements are described below to simplify the present disclosure. These are, of course, merely examples and are not intended to be limiting. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for the sake of simplicity and clarity.

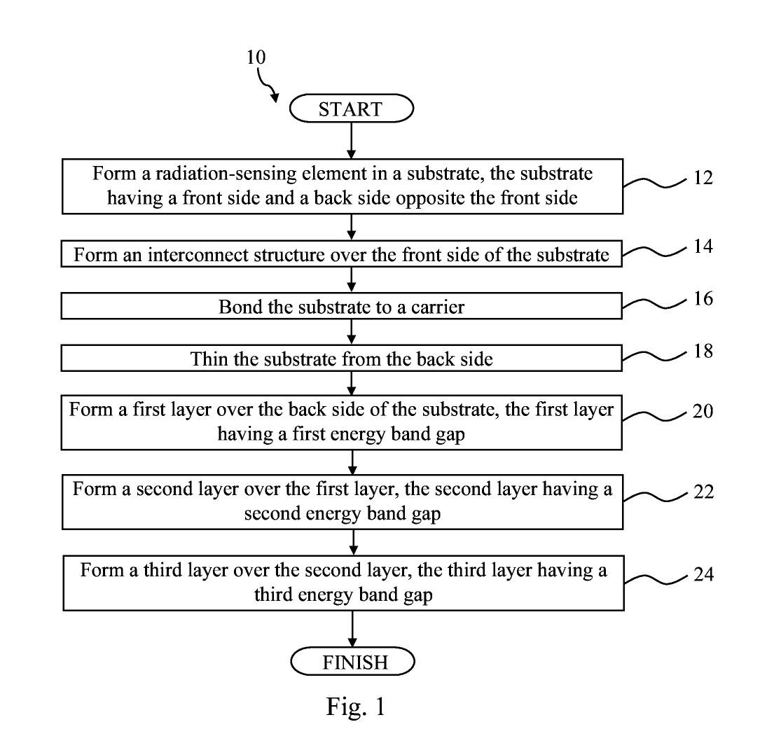

Illustrated in FIG. 1 is a flowchart of a method 10 for fabricating a semiconductor image sensor device according to various aspects of the present disclosure. Referring to FIG. 1, the method 10 begins with block 12 in which a radiation-sensing element is formed in a semiconductor substrate. The substrate has a front side and a back side opposite the front side. The radiation-sensing element is configured to sense radiation that enters the substrate from the back side.

The method 10 includes a step 14, in which an interconnect structure over the front side of the substrate.

The method 10 includes a step 16, in which the substrate is bonded to a carrier. The step 16 is performed in a manner such that the interconnect structure is disposed between the substrate and the carrier after the bonding.

The method 10 includes a step 18, in which the substrate is thinned from the back side after the bonding.

The method 10 includes a step 20, in which after the thinning, a first layer is formed over the back side of the substrate. The first layer has a first energy band gap. In some embodiments, the step 20 is performed such that the first layer contains silicon oxide and has a thickness in a range from about 10 angstroms to about 200 angstroms.

The method 10 includes a step 22, in which a second layer is formed over the first layer. The second layer has a second energy band gap. In some embodiments, the step 22 is performed such that the second layer contains hafnium oxide or silicon carbide and has a thickness in a range from about 300 angstroms to about 800 angstroms.

The method 10 includes a step 24, in which a third layer is formed over the second layer. The third layer has a third energy band gap. The second energy band gap is smaller than the first energy band gap and the second energy band gap. In some embodiments, the step 24 is performed such that the third layer contains silicon oxide and has a thickness in a range from about 30 angstroms to about 60 angstroms

It is understood that additional processing steps may be performed before, during, or after the method 10 of FIG. 1. For example, a nitride-containing passivation layer may be formed over the third layer. As another example, a lens may be formed over the passivation layer. For the sake of simplicity, additional processing steps are not discussed in detail herein.

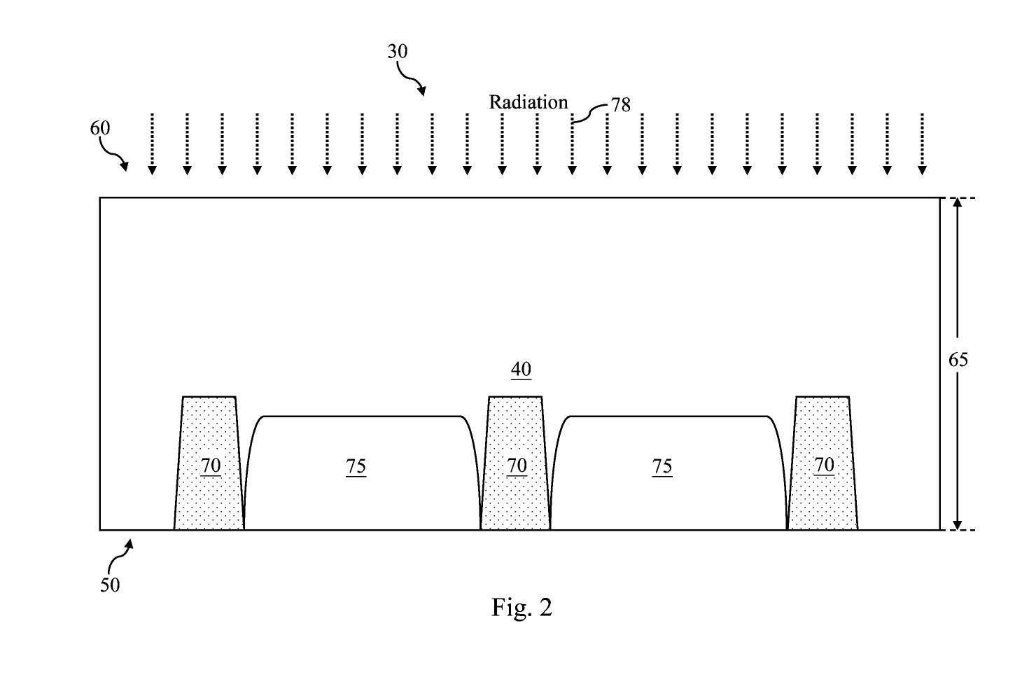

FIGS. 2-5 and 7 are diagrammatic fragmentary sectional side views of various embodiments of an apparatus that is a back side illuminated (BSI) image sensor device 30 at various stages of fabrication according to aspects of the method 10 of FIG. 1. The image sensor device 30 includes an array or grid of pixels for sensing and recording an intensity of radiation (such as light) directed toward a back-side of the image sensor device 30. The image sensor device 30 may include a charge-coupled device (CCD), complimentary metal oxide semiconductor (CMOS) image sensor (CIS), an active-pixel sensor (APS), or a passive-pixel sensor. The image sensor device 30 further includes additional circuitry and input/outputs that are provided adjacent to the grid of pixels for providing an operation environment for the pixels and for supporting external communication with the pixels. It is understood that FIGS. 2 to 5 have been simplified for a better understanding of the inventive concepts of the present disclosure and may not be drawn to scale.

With reference to FIG. 2, the image sensor device 30 includes a substrate 40, hereinafter referred to as a device substrate. The device substrate 40 is a silicon substrate doped with a p-type dopant such as Boron (for example a p-type substrate). Alternatively, the device substrate 40 could be another suitable semiconductor material. For example, the device substrate 40 may be a silicon substrate that is doped with an n-type dopant such as Phosphorous or Arsenic (an n-type substrate). The device substrate 40 could include other elementary semiconductors such as germanium and diamond. The device substrate 40 could optionally include a compound semiconductor and/or an alloy semiconductor. Further, the device substrate 40 could include an epitaxial layer (epi layer), may be strained for performance enhancement, and may include a silicon-on-insulator (SOI) structure.

Referring back to FIG. 2, the device substrate 40 has a front side (also referred to as a front surface) 50 and a back side (also referred to as a back surface) 60. For a BSI image sensor device such as the image sensor device 30, radiation is projected from the back side 60 and enters the substrate 40 through the back surface. The device substrate 40 also has an initial thickness 65. In some embodiments, the initial thickness 65 is in a range from about 100 microns (um) to about 3000 um, for example between about 500 um and about 1000 um.

A plurality of dielectric trench isolation (STI) structures 70 is formed in the substrate 40. In some embodiments, the STI structures 70 are formed by the following process steps: etching openings into the substrate 40 from the front side 50; filling the openings with a dielectric material such as silicon oxide, silicon nitride, silicon oxynitride, a low-k material, or another suitable dielectric material; and thereafter performing a polishing process—for example a chemical mechanical polishing (CMP) process—to planarize the surface of the dielectric material filling the openings. In some embodiments, deep trench isolation (DTI) structures may be formed. The formation processes for the DTI structures may be similar to the STI structures 70, though the DTI structures are formed to have greater depths than the STI structures 70. In certain embodiments, doped isolation structures may also be formed. These doped isolation structures may be formed by one or more ion implantation processes. The doped isolation structures may be formed to replace or to supplement the STI or DTI structures.

A plurality of pixels is formed in the substrate 40. The pixels contain radiation-sensing doped regions 75. These radiation-sensing doped regions 75 are formed by one or more ion implantation processes or diffusion processes and are doped with a doping polarity opposite from that of the substrate 40. Thus, in the embodiment illustrated, the pixels contain n-type doped regions. For a BSI image sensor device such as the image sensor device 30, the pixels are configured to detect radiation, such as an incident light 78, that is projected toward device substrate 40 from the back side 60.

In some embodiments, the pixels each include a photodiode. A deep implant region may be formed below each photodiode in some embodiments. In other embodiments, the pixels may include pinned layer photodiodes, photogates, reset transistors, source follower transistors, and transfer transistors. The pixels may also be referred to as radiation-detection devices or light-sensors. The pixels may be varied from one another to have different junction depths, thicknesses, widths, and so forth. It is understood that each pair of adjacent or neighboring pixels may be separated from each other by a respective one of the isolation structures 70 discussed above.

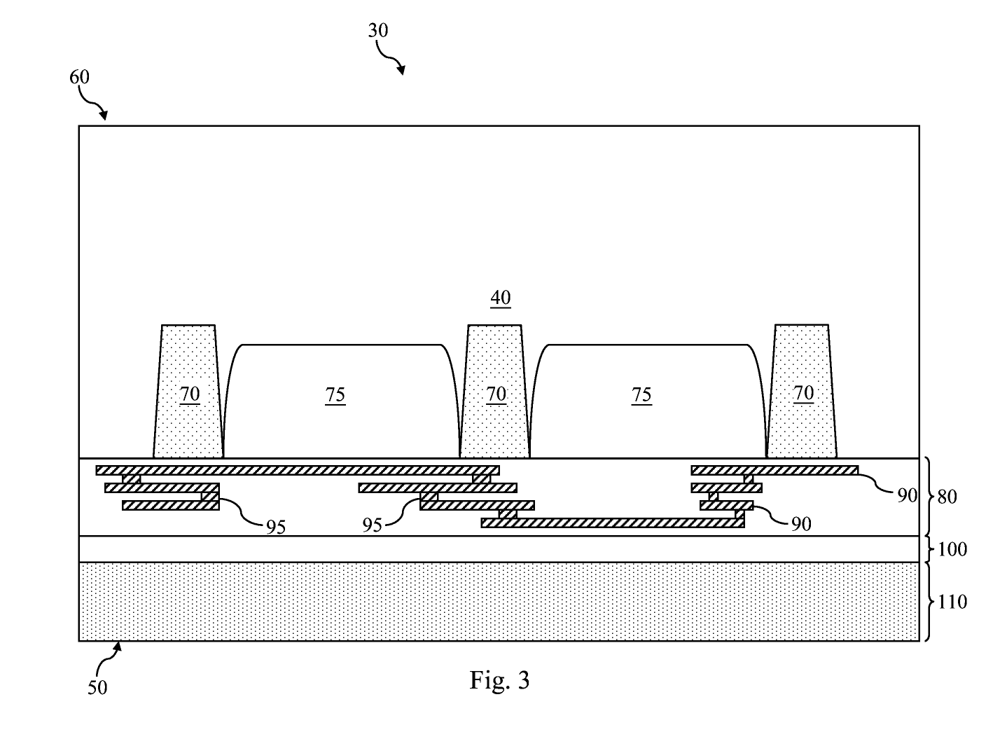

Referring now to FIG. 3, an interconnect structure 80 is formed over the front side 50 of the device substrate 40. The interconnect structure 80 includes a plurality of patterned dielectric layers and conductive layers that provide interconnections (e.g., wiring) between the various doped features, circuitry, and input/output of the image sensor device 30. The interconnect structure 80 includes an interlayer dielectric (ILD) and a multilayer interconnect (MLI) structure. The MLI structure includes contacts, vias and metal lines. For purposes of illustration, a plurality of conductive lines 90 and vias/contacts 95 are shown in FIG. 3, it being understood that the conductive lines 90 and vias/contacts 95 illustrated are merely exemplary, and the actual positioning and configuration of the conductive lines 90 and vias/contacts 95 may vary depending on design needs and manufacturing concerns.

The MLI structure may include conductive materials such as aluminum, aluminum/silicon/copper alloy, titanium, titanium nitride, tungsten, polysilicon, metal silicide, or combinations thereof, being referred to as aluminum interconnects. Aluminum interconnects may be formed by a process including physical vapor deposition (PVD) (or sputtering), chemical vapor deposition (CVD), atomic layer deposition (ALD), or combinations thereof. Other manufacturing techniques to form the aluminum interconnect may include photolithography processing and etching to pattern the conductive materials for vertical connection (for example, vias/contacts 95) and horizontal connection (for example, conductive lines 90). Alternatively, a copper multilayer interconnect may be used to form the metal patterns. The copper interconnect structure may include copper, copper alloy, titanium, titanium nitride, tantalum, tantalum nitride, tungsten, polysilicon, metal silicide, or combinations thereof. The copper interconnect structure may be formed by a technique including CVD, sputtering, plating, or other suitable processes.

Still referring to FIG. 3, a buffer layer 100 is formed on the interconnect structure 80. In the present embodiment, the buffer layer 100 includes a dielectric material such as silicon oxide. Alternatively, the buffer layer 100 may optionally include silicon nitride. The buffer layer 100 is formed by CVD, PVD, or other suitable techniques. The buffer layer 100 is planarized to form a smooth surface by a CMP process.

Thereafter, a carrier substrate 110 is bonded with the device substrate 40 through the buffer layer 100, so that processing of the back side 60 of the device substrate 40 can be performed. The carrier substrate 110 in the present embodiment is similar to the substrate 40 and includes a silicon material. Alternatively, the carrier substrate 110 may include a glass substrate or another suitable material. The carrier substrate 110 may be bonded to the device substrate 40 by molecular forces—a technique known as direct bonding or optical fusion bonding—or by other bonding techniques known in the art, such as metal diffusion or anodic bonding.

Referring back to FIG. 3, the buffer layer 100 provides electrical isolation between the device substrate 40 and the carrier substrate 110. The carrier substrate 110 provides protection for the various features formed on the front side 50 of the device substrate 40, such as the pixels formed therein. The carrier substrate 110 also provides mechanical strength and support for processing of the back side 60 of the device substrate 40 as discussed below. After bonding, the device substrate 40 and the carrier substrate 110 may optionally be annealed to enhance bonding strength.

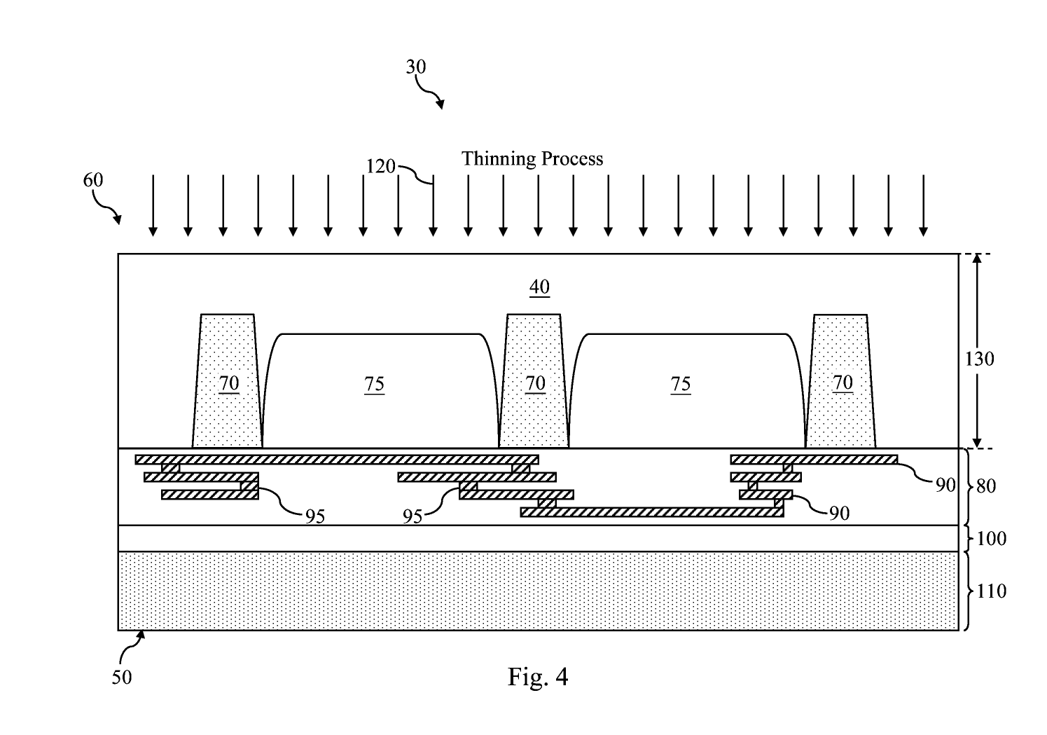

Referring now to FIG. 4, after the carrier substrate 110 is bonded, a thinning process 120 is then performed to thin the device substrate 40 from the backside 60. The thinning process 120 may include a mechanical grinding process and a chemical thinning process. A substantial amount of substrate material may be first removed from the device substrate 40 during the mechanical grinding process. Afterwards, the chemical thinning process may apply an etching chemical to the back side 60 of the device substrate 40 to further thin the device substrate 40 to a thickness 130, which is on the order of a few microns. In some embodiments, the thickness 130 is greater than about 1 um but less than about 3 um. It is also understood that the particular thicknesses disclosed in the present disclosure are mere examples and that other thicknesses may be implemented depending on the type of application and design requirements of the image sensor device 30.

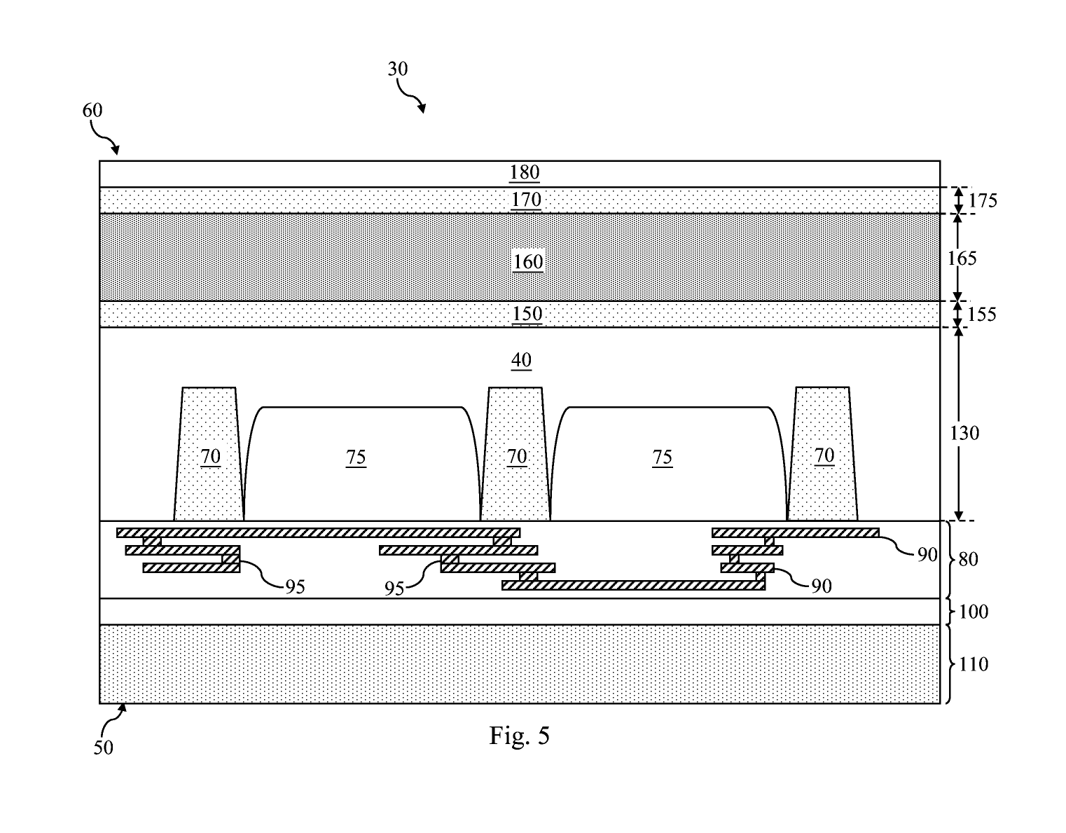

Referring now to FIG. 5, a layer 150 is formed over the back side 60 of the thinned-down substrate 40. The layer 150 contains a material having a high energy band gap. In other words, a bottom level of a conduction band (E_{C}) is relatively high for the material of the layer 150. In some embodiments, the layer 150 contains a dielectric material, for example silicon oxide. The layer 150 also has a thickness 155 (a vertical dimension). In certain embodiments, the thickness 155 is configured to be appropriate for preventing charges or charge carriers from moving to the substrate 40 below. The configuring of the thickness 155 for the layer 150 will be discussed in greater detail below. In some embodiments, the thickness 155 is greater than about 5 angstroms, for example in a range from about 10 angstroms to about 500 angstroms.

A layer 160 is formed over the layer 150. The layer 160 contains a material having a low energy band gap. In other words, a bottom level of a conduction band (E_{C}) is relatively low for the material of the layer 160, for example lower than the bottom level of the conduction band for the material of the layer 150. The layer 160 also has a thickness 165. In certain embodiments, the material composition of the layer 160 as well as its thickness 165 are both configured to store charges or charge carriers. In other words, the material composition of the 160 and its thickness 165 are chosen to trap excess charge carriers inside the layer 160, so that these charge carriers will not move to the silicon substrate 40. In some embodiments, the layer 160 contains a dielectric material, for example silicon carbide. In other embodiments, the layer 160 contains a low-k dielectric material, for example hafnium oxide. In some embodiments, the thickness 165 of the layer 160 is greater than about 5 angstroms, for example in a range from about 20 angstroms to about 800 angstroms.

A layer 170 is formed over the layer 160. The layer 170 contains a material having a high energy band gap. In other words, a bottom level of a conduction band (E_{C}) is relatively high for the material of the layer 170, for example greater than the bottom level of the conduction band for the material of the layer 160. The layer 170 also has a thickness 175. In certain embodiments, the material composition of the layer 170 as well as its thickness 175 are both configured to prevent charge carriers from moving to the silicon substrate 40. In some embodiments, the layer 170 contains a dielectric material, for example silicon carbide. In some embodiments, the thickness 175 of the layer 170 is greater than about 10 angstroms, for example in a range from about 10 angstroms to about 5000 angstroms.

A passivation layer 180 is then optionally formed over the layer 170. The passivation layer 180 protects the layers underneath from humidity, dust, stress, etc. In some embodiments, the passivation 180 contains a silicon nitride material.

It is understood that only a “pixel array” region of the image sensor device 30 is illustrated in FIGS. 2-5. As discussed above, the “pixel array” region contains pixels that are configured to detect light from the back side 60. The image sensor device 30 may further include other regions that are not illustrated for reasons of simplicity. For example, the image sensor device 30 may include a black level correction region. The black level correction region contains one or more reference pixels formed in the device substrate 40 that need to be kept optically dark, so as to set a baseline reference. A light-blocking element, such as a metal shield, may be formed over the back side 60 of the black level correction region. This light-blocking element helps keep the reference pixel(s) below optically dark. The image sensor device 30 may further include other regions such as a bonding pad region reserved for the formation of bonding pads, so that electrical connections between the image sensor device 30 and external devices may be established, or a periphery region that include digital devices, such as application-specific integrated circuit (ASIC) devices or system-on-chip (SOC) devices, or a scribe line region. Again, these regions are omitted from being illustrated herein for reasons of simplicity.

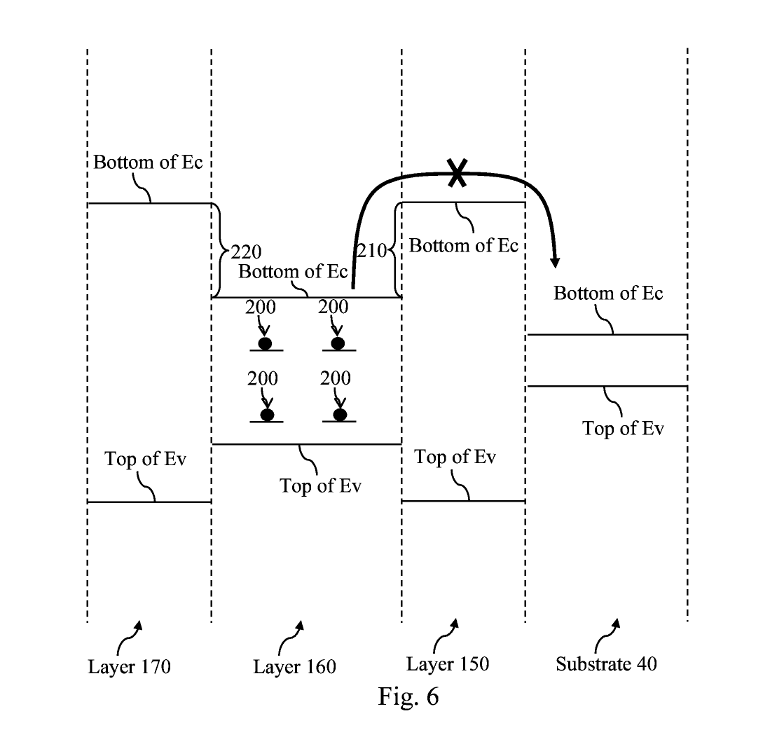

The stack of layers 150, 160, and 170 collectively form a “high-low-high” structure in terms of energy band gaps. In more detail, referring now to FIG. 6, a simplified energy band diagram is illustrated for the substrate 40 and the stack formed by the layers 150/160/170. Starting from the right and moving to the left, the energy band diagrams are respectively illustrated for the substrate 40, the layer 150, the layer 160, and the layer 170. For each of these layers, there exists a conduction band (E_{C}) and a valence band (E_{V}). The conduction band E_{C} is located above the valence band E_{V}. The bottom of the conduction band E_{C} and the top of the valence band E_{V} is shown for the substrate 40 and for each of the layers 150, 160, and 170.

As is illustrated in FIG. 6, since the material of the layer 160 is a low energy band gap material, its bottom level of the conduction band E_{C} is lower than the layers 150 and 170, which contain high energy band gap materials. Stated differently, the bottom levels of the conduction band E_{C} for the layers 150 and 170 are both higher than the bottom level of the conduction band E_{C} for the layer 160. This high-low-high band gap configuration is desirable because it helps the layer 160 trap charge carriers, such as example charger carriers 200, inside the layer 160. In more detail, if excess charge such as the charger carriers 200 move into the substrate 40, they will cause performance degradation for the image sensor device. The performance degradation may include white pixel, dark current, dark image non-uniformity, etc. Therefore, it is desirable to keep the charge carriers 200 inside the layer 160 and prevent their movement to the substrate 40.

Here, the layer 150 is configured to have a high energy band gap, in other words, a high level for its bottom conduction band E_{C}. On the other hand, the layer 160 is configured to have a low energy band gap, in other words, a low level for its bottom conduction band E_{C}. For charge carriers 200 to move into the substrate, they must go through the layer 150 first. However, a band gap differential 210 exists between the layers 150 and 160. The band gap differential 210 is the difference between the bottom of the conduction band E_{C} for the layer 150 and the bottom of the conduction band E_{C} for the layer 160. This band gap differential 210 is difficult for the charge carriers 200 to overcome. Therefore, the movement of the charge carriers 200 toward the substrate 40 is substantially reduced. It is understood that, the steeper (greater) the band gap differential 210, the more difficult it is for the charge carriers 200 to go through the layer 150 and move into the substrate 40. As such, the charge carriers 200 are effectively trapped inside the layer 160, thereby reducing or alleviating the performance degradations for the image sensor discussed above.

Similarly, a band gap differential 220 exists between the layers 160 and 170 as well, since the layer 170 is also configured to have a greater level for its bottom conduction band E_{C} than that of the layer 160. This band gap differential 220 also restricts the movement of the charge carriers 200. It is desirable to restrict the movement of the charge carriers, because their movement into the silicon substrate may cause dark current and impact the performance of CMOS image sensors.

Based on the above discussions, it can be seen that the disposition of the layer 160 (with the low energy band gap) between the layers 150 and 170 (with the high energy band gaps) effectively creates a quantum well, which helps confine the charge carriers within the layer 160.

It is also understood that, in some embodiments, one or more of the layers 150, 160, and 170 may be doped to further enhance the band gap differential 210.

In addition to the energy band differentials 210/220 discussed above, the present disclosure also configures the thickness 165 (shown in FIG. 5) of the layer 160 to further prevent the charge carriers 200 from moving into the substrate 40. In some embodiments, the thickness 165 is selected to be large enough to reduce a “quantum tunneling effect.” The quantum tunneling effect refers to a phenomenon in which an object moves beyond a barrier that it could not surmount under classical physics, but somehow the object will reappear on the other side of the barrier after a certain amount of time. Applied in the present context, the quantum tunneling effect may be associated with the charge carriers 200 overcoming the layer 150 (i.e., the “barrier”) and appearing on the other side of the layer 150 even though the charge particles are not supposed to be able to overcome the barrier that is the layer 150.

The occurrence (or the likelihood of the occurrence) of the quantum tunneling effect is dependent the distance that the object has to travel through the barrier. In this case, that variable is the thickness 155 of the layer 150. According to the various aspects of the present disclosure, the thickness 155 can be expressed with the following mathematical equation:

d=h/[square root of (2*m*ΔE)]

wherein d represents a minimum thickness of the first layer, h represents Planck's constant (6.626068×10⁻³⁴ m²kg/s), m represents an electron mass (9.10938188×10⁻³¹ kg), and ΔE represents the difference between the energy band gaps (i.e., the energy band differential 210) of the barrier layer (i.e., the layer 150) and the layer in which the object resides (i.e., the layer 160). In more plain English, the above equation basically states that, the thickness 155 of the layer is set to be greater than or equal to: (Planck's constant) divided by [square root of (2*electron mass*the difference between the bottom conduction band level of the layer 150 and the second bottom conduction band level of the layer 160)]. Therefore, the minimum level of the thickness 155 can be calculated once the material compositions for the layers 150 and 160 are chosen, since Planck's constant and electron mass are constants. Of course, if the thickness 155 is set to greatly exceed the minimum value d, the quantum tunneling effect may be further reduced. However, a thicker layer 150 may be undesirable in other respects, as it may increase overall device size or fabrication costs. A more optimum value for the thickness 155 should be greater than the minimum thickness d, but not by too much.

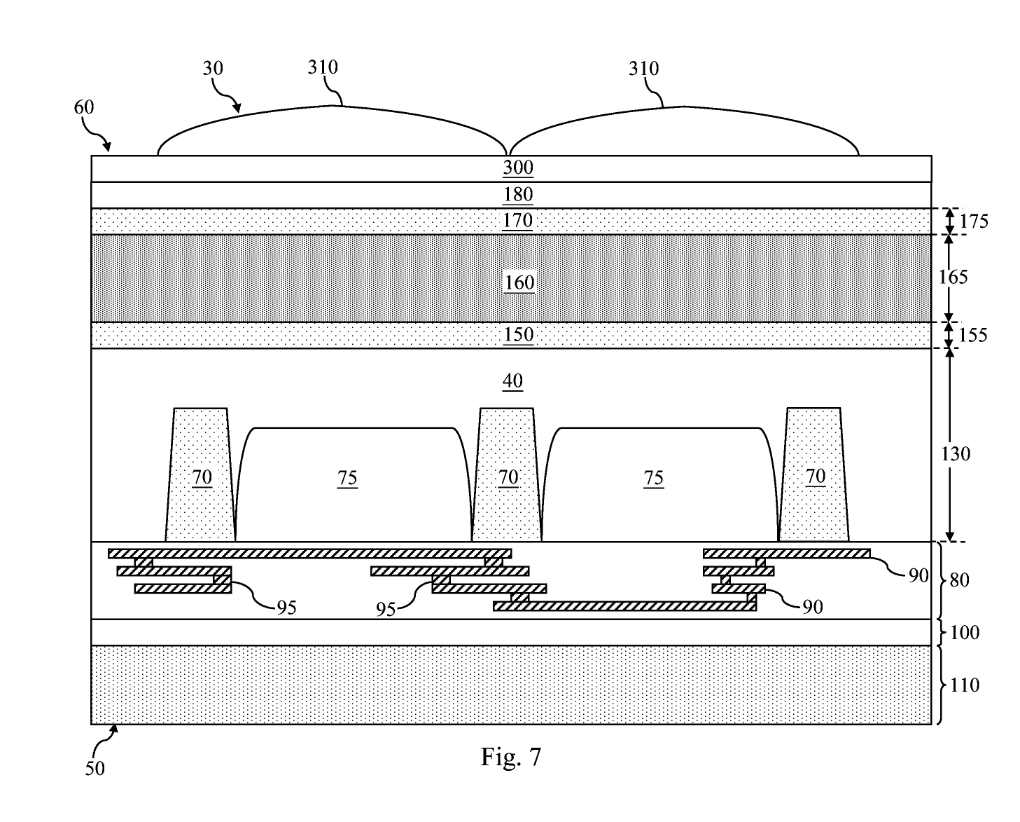

Referring now to FIG. 7, additional fabrication processes may be performed to complete the fabrication of the image sensor device 40. For example, a color filter layer 300 may be formed over the layer 180 from the back side 60. The color filter layer 300 may contain a plurality of color filters that may be positioned such that the incoming radiation is directed thereon and therethrough. The color filters may include a dye-based (or pigment based) polymer or resin for filtering a specific wavelength band of the incoming radiation, which corresponds to a color spectrum (e.g., red, green, and blue).

Thereafter, a micro-lens layer containing a plurality of micro-lenses 310 is formed over the color filter layer. The micro-lenses direct and focus the incoming radiation toward specific radiation-sensing regions in the device substrate 40. The micro-lenses may be positioned in various arrangements and have various shapes depending on a refractive index of a material used for the micro-lens and distance from a sensor surface. The device substrate 40 may also undergo an optional laser annealing process before the forming of the color filter layer or the micro-lens layer.

It is understood that the sequence of the fabrication processes described above is not intended to be limiting. Some of the layers or devices may be formed according to different processing sequences in other embodiments than what is shown herein. Furthermore, some other layers may be formed but are not illustrated herein for the sake of simplicity.

The embodiments discussed above offer advantages over conventional image sensor devices, for example advantages with respect to white pixel, dark current, or dark image non-uniformity. However, it is understood that not all advantages are necessarily discussed herein, and other embodiments may offer different advantages, and that no particular advantage is required for all embodiments.

As discussed above, if excessive charge carriers were allowed to propagate to the radiation-sensitive pixels in the substrate, they may cause defects such as white pixels, dark current, or dark image non-uniformity. As an example, dark current is a common type of image sensor defect and may be defined as the existence of pixel current when no actual illumination is present. In other words, the pixel “detects” light when it is not supposed to. Dark current, or other types of defects discussed above, may be attributed to the leakage current generated by the excess charge carriers. Traditional image sensors have not produced an adequate mechanism for trapping these excess charge carriers or otherwise prevent their propagation into the substrate.

In comparison, the image sensor device 30 discussed above utilized a unique and optimized film stacking scheme to optimally trap the excess charge carriers within. For example, the high-low-high energy band gap scheme formed by the layers 150, 160, and 170 creates a high band gap differential between the layers 160 and 150. The excess charge carriers in the layer 160 cannot overcome the barrier caused the band gap differential and as such are substantially trapped inside the layer 160. In addition, the thickness of the layer 150 is optimized to minimum a quantum tunneling effect in which the charge carriers would have “tunneled through” the layer 150 to arrive at the substrate. Here, the optimized thickness layer 150 substantially reduces the likelihood of the charge carriers being able to tunnel through the layer 150, again helping to trap the charge carriers within the layer 160. Since very few charge carriers can propagate to the radiation-sensing regions in the substrate, the performance degradations such as white pixel, dark current, or dark image non-uniformity are substantially reduced.

One aspect of the present disclosure involves a semiconductor image sensor device. The semiconductor device includes: a semiconductor substrate having a first side and a second side opposite the first side, wherein the semiconductor substrate contains a radiation-sensing region configured to sense radiation projected toward the substrate from the second side; a first layer disposed over the second side of the semiconductor substrate, the first layer having a first energy band gap; a second layer disposed over the first layer, the second layer having a second energy band gap; and a third layer disposed over the second layer, the third layer having a third energy band gap; wherein the second energy band gap is smaller than the first energy band gap and the third energy band gap.

Another aspect of the present disclosure involves a semiconductor image sensor device. The semiconductor image sensor device includes: a substrate having a front surface and a back surface, the substrate containing one or more radiation-sensitive pixels configured to detect radiation that enters the substrate through the back surface; an interconnect structure located over the front surface of the substrate; a first layer located over the back surface of the substrate, the first layer containing a first material selected to have a first bottom conduction band level; a second layer located over the first layer, the second layer containing a second material selected to have a second bottom conduction band level; and a third layer located over the second layer, the third layer containing a third material selected to have a third bottom conduction band level; wherein the second bottom conduction band level is less than the first bottom conduction band level and the third bottom conduction band level.

Yet another aspect of the present disclosure involves a method of fabricating a semiconductor image sensor device. The method includes: forming a radiation-sensing element in a substrate, the substrate having a front side and a back side opposite the front side, wherein the radiation-sensing element is configured to sense radiation that enters the substrate from the back side; forming an interconnect structure over the front side of the substrate; bonding the substrate to a carrier in a manner such that the interconnect structure is disposed between the substrate and the carrier; thinning, after the bonding, the substrate from the back side; forming, after the thinning, a first layer over the back side of the substrate, the first layer having a first energy band gap; forming a second layer over the first layer, the second layer having a second energy band gap; and forming a third layer over the second layer, the third layer having a third energy band gap; wherein the second energy band gap is smaller than the first energy band gap and the second energy band gap.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor image sensor device, comprising:
a semiconductor substrate having a first side and a second side opposite the first side, wherein the semiconductor substrate contains a radiation-sensing region configured to sense radiation projected toward the substrate from the second side;
a first layer disposed over the second side of the semiconductor substrate, the first layer having a first energy band gap;
a second layer disposed over the first layer, the second layer having a second energy band gap; and
a third layer disposed over the second layer, the third layer having a third energy band gap;
wherein the second energy band gap is smaller than the first energy band gap and the third energy band gap.

2. The semiconductor image sensor device of claim 1, wherein;
the first layer contains silicon oxide;
the second layer contains hafnium oxide or silicon carbide; and
the third layer contains silicon oxide.

3. The semiconductor image sensor device of claim 1, further comprising: a passivation layer disposed over the third layer.

4. The semiconductor image sensor device of claim 3, wherein the passivation layer contains silicon nitride.

5. The semiconductor image sensor device of claim 1, wherein a thickness of the first layer is a function of a difference between the first energy band gap and the second energy band gap.

6. The semiconductor image sensor device of claim 5, wherein the function is expressed as: d=h/[square root of (2*m*ΔE)], wherein d represents a minimum thickness of the first layer, h represents Planck's constant, m represents an electron mass, and ΔE represents the difference between the first energy band gap and the second energy band gap.

7. The semiconductor image sensor device of claim 1, wherein:
the first layer has a thickness in a range from about 10 angstroms to about 500 angstroms;
the second layer has a thickness in a range from about 20 angstroms to about 800 angstroms; and
the third layer has a thickness in a range from about 10 angstroms to about 5000 angstroms.

8. The semiconductor image sensor device of claim 1, further comprising:
a lens disposed over the passivation layer on the second side; and
an interconnect structure disposed over the first side of the substrate.

9. A semiconductor image sensor device, comprising:
a substrate having a front surface and a back surface, the substrate containing one or more radiation-sensitive pixels configured to detect radiation that enters the substrate through the back surface;
an interconnect structure located over the front surface of the substrate;
a first layer located over the back surface of the substrate, the first layer containing a first material selected to have a first bottom conduction band level;
a second layer located over the first layer, the second layer containing a second material selected to have a second bottom conduction band level; and
a third layer located over the second layer, the third layer containing a third material selected to have a third bottom conduction band level;
wherein the second bottom conduction band level is less than the first bottom conduction band level and the third bottom conduction band level.

10. The semiconductor image sensor device of claim 9, wherein;
the first layer contains silicon oxide and has a thickness in a range from about 10 angstroms to about 500 angstroms;
the second layer contains hafnium oxide or silicon carbide and has a thickness in a range from about 20 angstroms to about 800 angstroms; and
the third layer contains silicon oxide and has a thickness in a range from about 10 angstroms to about 5000 angstroms.

11. The semiconductor image sensor device of claim 9, further comprising: a passivation layer located over the third layer.

12. The semiconductor image sensor device of claim 11, wherein the passivation layer contains silicon nitride.

13. The semiconductor image sensor device of claim 9, wherein a thickness of the first layer is correlated with a difference between the first bottom conduction band level and the second bottom conduction band level.

14. The semiconductor image sensor device of claim 13, wherein the thickness is greater than or equal to: (Planck's constant) divided by [square root of (2*electron mass*the difference between the first bottom conduction band level and the second bottom conduction band level)].

15. The semiconductor image sensor device of claim 9, further comprising a color filter and a micro-lens disposed located over the passivation layer.

16. A method of fabricating a semiconductor image sensor device, comprising:
forming a radiation-sensing element in a substrate, the substrate having a front side and a back side opposite the front side, wherein the radiation-sensing element is configured to sense radiation that enters the substrate from the back side;
forming an interconnect structure over the front side of the substrate;
bonding the substrate to a carrier in a manner such that the interconnect structure is disposed between the substrate and the carrier;
thinning, after the bonding, the substrate from the back side;
forming, after the thinning, a first layer over the back side of the substrate, the first layer having a first energy band gap;
forming a second layer over the first layer, the second layer having a second energy band gap; and
forming a third layer over the second layer, the third layer having a third energy band gap;
wherein the second energy band gap is smaller than the first energy band gap and the second energy band gap.

17. The method of claim 16, wherein;
the forming the first layer is performed such that the first layer contains silicon oxide and has a thickness in a range from about 10 angstroms to about 500 angstroms;
the forming the second layer is performed such that the second layer contains hafnium oxide or silicon carbide and has a thickness in a range from about 20 angstroms to about 800 angstroms; and
the forming the third layer is performed such that the third layer contains silicon oxide and has a thickness in a range from about 10 angstroms to about 5000 angstroms.

18. The method of claim 16, further comprising:
forming a nitride-containing passivation layer over the third layer; and
forming a lens over the passivation layer.

19. The method of claim 16, wherein the forming the first layer comprises:
configuring a thickness of the first layer as a function of a difference between the first energy band gap and the second energy band gap.

20. The method of claim 19, wherein the function is expressed as: d=h/[square root of (2*m*ΔE)], wherein d represents a minimum thickness of the first layer, h represents Planck's constant, m represents an electron mass, and ΔE represents the difference between the first energy band gap and the second energy band gap.
